(19) United States
(12) Patent Application Publication
(10) Pub. No.: US 2025/0048732 A1
(43) Pub. Date: Feb. 6, 2025

(54) DISPLAY PANELS AND PREPARATION METHODS THEREOF

(71) Applicant: Guangzhou China Star Optoelectronics Semiconductor Display Technology Co., LTd., Guangzhou, Guangdong (CN)

(72) Inventors: Bichan ZHAO, Guangzhou, Guangdong (CN); Fen LONG, Guangzhou, Guangdong (CN)

(73) Assignee: Guangzhou China Star Optoelectronics Semiconductor Display Technology Co., LTd., Guangzhou, Guangdong (CN)

(21) Appl. No.: 18/263,540

(22) PCT Filed: Jun. 5, 2023
(86) PCT No.: PCT/CN2023/098334

§ 371 Date: Jul. 31, 2023

(30) Foreign Application Priority Data
May 15, 2023 (CN) 202310549078.8

(51) Int. Cl. H01L 27/12; G02F 1/1362; G02F 1/1368

(52) U.S. Cl. CPC H01L 27/124; G02F 1/136209; G02F 1/136295; G02F 1/1368; H01L 27/127

(57) ABSTRACT

The disclosure provides a display panel and a preparation method thereof. The display panel includes an array substrate and an opposite substrate. The array substrate includes a first substrate, a common electrode layer, a first metal layer, a second substrate, and a light-shielding layer. The common electrode layer includes a common electrode, a first electrode, and a groove, and the groove is disposed between the common electrode and the first electrode. The light-shielding layer includes a light-shielding part, and an orthographic projection of the light-shielding part on the first substrate covers an orthographic projection of the first electrode on the first substrate, an orthographic projection of the second electrode on the first substrate, and an orthographic projection of the groove on the first substrate.

### TECHNICAL FIELD

The disclosure relates to the field of display, in particular to display panels and preparation methods thereof.

### BACKGROUND

The same film layer in the existing display panel includes multiple electrodes with different polarity. In order to avoid the connection between the electrodes with different polarity or signal crosstalk, it is necessary to separate the multiple electrodes with different polarity. Due to the need for shading at the spacing of the electrodes, the area required for shading in a pixel unit of the display panel is larger, resulting in a lower opening rate.

### SUMMARY

The disclosure provides a display panel and a preparation method thereof, which can reduce the area required for shading in a pixel unit and improve the opening rate of the display panel.

On the one hand, embodiments of the disclosure provide a display panel, which includes an array substrate and an opposite substrate. The array substrate includes a first substrate, a common electrode layer, and a first metal layer. The common electrode layer is disposed on the first substrate and includes a common electrode, a first electrode, and a groove, and the groove is disposed between the common electrode and the first electrode. The first metal layer is disposed on a side of the common electrode layer away from the first substrate and includes a gate and a second electrode, the gate is disposed on the first electrode, and the second electrode is disposed on the common electrode. The opposite substrate is disposed opposite to the array substrate and includes a second substrate and a light-shielding layer. The light-shielding layer is disposed on a side of the second substrate close to the array substrate and includes a light-shielding part. An orthographic projection of the light-shielding part on the first substrate covers an orthographic projection of the first electrode on the first substrate, an orthographic projection of the second electrode on the first substrate, and an orthographic projection of the groove on the first substrate.

Optionally, in some embodiments of the disclosure, the common electrode layer may include multiple common electrodes disposed at intervals, and the first electrode may be disposed between adjacent two of the common electrodes arranged along a first direction. Two opposite sides of the first electrode may be respectively provided with the groove, and the orthographic projection of the light-shielding part on the first substrate may cover an orthographic projection of two grooves on the first substrate.

Optionally, in some embodiments of the disclosure, a width of a cross-sectional surface of the light-shielding part along the first direction may range from 40 microns to 45 microns.

Optionally, in some embodiments of the disclosure, the array substrate may include a gate insulation layer, a semiconductor layer, and a second metal layer. The gate insulation layer may cover the common electrode layer and the first metal layer. The semiconductor layer may be disposed on a side of the gate insulation layer away from the first substrate. An orthographic projection of the semiconductor layer on the first substrate may cover an orthographic projection of the gate on the first substrate. The second metal layer may be disposed on a side of the semiconductor layer away from the first substrate and include a source, a drain, and a data line. The source and the drain may be disposed at intervals, and the data line may be disposed at a side of the source away from the drain and connected to the source. The data line may extend along the first direction.

Optionally, in some embodiments of the disclosure, the array substrate may include a passivation layer, and the passivation layer may cover the semiconductor layer and the second metal layer. The passivation layer may be provided with a via hole disposed corresponding to the drain.

Optionally, in some embodiments of the disclosure, the array substrate may include a pixel electrode layer disposed on a side of the passivation layer away from the first substrate. The pixel electrode layer may include a pixel electrode, and the pixel electrode may be connected to the drain through the via hole.

Optionally, in some embodiments of the disclosure, the pixel electrode layer may include a third electrode disposed between two adjacent pixel electrodes arranged along a second direction, and the first direction may be perpendicular to the second direction. An orthographic projection of the third electrode on the first substrate may at least partially cover an orthographic projection of the data line on the first substrate.

Optionally, in some embodiments of the disclosure, a polarity of the third electrode and a polarity of the pixel electrode may be same.

Optionally, in some embodiments of the disclosure, a width of a cross-sectional surface of the third electrode along the first direction may be equal to a width of a cross-sectional surface of the pixel electrode along the first direction.

Optionally, in some embodiments of the disclosure, the third electrode may include at least two first electrode parts and a second electrode part. Each of the first electrode parts may be disposed between two adjacent pixel electrodes arranged along the second direction, and the second electrode part may be disposed between two adjacent first electrode parts. A width of a cross-sectional surface of each of the first electrode parts along the second direction and a width of a cross-sectional surface of the second electrode part along the second direction may be not equal.

Optionally, in some embodiments of the disclosure, a width of a cross-sectional surface of the groove along the first direction may range from 7 microns to 8 microns.

On the other hand, embodiments of the disclosure further provide a preparation method of a display panel. The display panel includes an array substrate and an opposite substrate, and a preparation method of the array substrate includes: forming a common electrode layer and a first metal layer sequentially on a first substrate; etching the first metal layer and the common electrode layer to form a first electrode, a common electrode, a gate, and a second electrode by using a first mask process, in which the gate is disposed on the first electrode, and the second electrode is disposed on the common electrode; forming a gate insulation layer on the first metal layer and the common electrode layer; forming a semiconductor layer and a second metal layer sequentially on the gate insulation layer; etching the semiconductor layer and the second metal layer to form an active layer, a source, a drain, and a data line by using a second mask process, in which the active layer is disposed on the gate, the source and the drain are disposed on the active layer, and the data line is disposed at a side of the source away from the drain; forming a passivation layer on the second metal layer and the semiconductor layer; etching the passivation layer to form a via hole by using a third mask process, in which the via hole is disposed on the drain; forming a pixel electrode layer on the passivation layer; and etching the pixel electrode layer to form a pixel electrode by using a fourth mask process, in which the pixel electrode is disposed at least partially overlapping with the common electrode, and the pixel electrode is connected to the drain through the via hole. The preparation method of the display panel further includes the step of integrating the array substrate with the opposite substrate. The opposite substrate includes a second substrate and a light-shielding layer. The light-shielding layer is disposed on a side of the second substrate close to the array substrate and includes a light-shielding part. An orthographic projection of the light-shielding part on the first substrate covers an orthographic projection of the first electrode on the first substrate, an orthographic projection of the second electrode on the first substrate, and an orthographic projection of the groove on the first substrate.

Optionally, in some embodiments of the disclosure, the common electrode layer may include multiple common electrodes disposed at intervals, and the first electrode may be disposed between adjacent two of the common electrodes arranged along a first direction. Two opposite sides of the first electrode may be respectively provided with the groove, and the orthographic projection of the light-shielding part on the first substrate may cover an orthographic projection of two grooves on the first substrate.

Optionally, in some embodiments of the disclosure, a width of a cross-sectional surface of the light-shielding part along the first direction may range from 40 microns to 45 microns.

Optionally, in some embodiments of the disclosure, the array substrate may include a gate insulation layer, a semiconductor layer, and a second metal layer. The gate insulation layer may cover the common electrode layer and the first metal layer. The semiconductor layer may be disposed on a side of the gate insulation layer away from the first substrate, and an orthographic projection of the semiconductor layer on the first substrate may cover an orthographic projection of the gate on the first substrate. The second metal layer may be disposed on a side of the semiconductor layer away from the first substrate and include a source, a drain, and a data line. The source and the drain may be disposed at intervals. The data line may be disposed at a side of the source away from the drain and connected to the source. The data line may extend along the first direction.

Optionally, in some embodiments of the disclosure, the array substrate may include a passivation layer, and the passivation layer may cover the semiconductor layer and the second metal layer. The passivation layer may be provided with a via hole disposed corresponding to the drain.

Optionally, in some embodiments of the disclosure, the array substrate may include a pixel electrode layer disposed on a side of the passivation layer away from the first substrate. The pixel electrode layer may include a pixel electrode, and the pixel electrode may be connected to the drain through the via hole.

Optionally, in some embodiments of the disclosure, the pixel electrode layer may include a third electrode disposed between two adjacent pixel electrodes arranged along a second direction. The first direction may be perpendicular to the second direction. An orthographic projection of the third electrode on the first substrate may at least partially cover an orthographic projection of the data line on the first substrate.

Optionally, in some embodiments of the disclosure, a width of a cross-sectional surface of the third electrode along the first direction may be equal to a width of a cross-sectional surface of the pixel electrode along the first direction.

Optionally, in some embodiments of the disclosure, the third electrode may include at least two first electrode parts and a second electrode part. Each of the first electrode parts may be disposed between two adjacent pixel electrodes arranged along the second direction, and the second electrode part may be disposed between two adjacent first electrode parts. A width of a cross-sectional surface of each of the first electrode parts along the second direction and a width of a cross-sectional surface of the second electrode part along the second direction may be not equal.

Optionally, in some embodiments of the disclosure, a width of a cross-sectional surface of the groove along the first direction may range from 7 microns to 8 microns.

### Beneficial Effects

The disclosure provides a display panel and a preparation method thereof. The display panel includes an array substrate and an opposite substrate. The array substrate includes a first substrate, a common electrode layer, and a first metal layer. The common electrode layer is disposed on the first substrate and includes a common electrode, a first electrode, and a groove, and the groove is disposed between the common electrode and the first electrode. The first metal layer is disposed on a side of the common electrode layer away from the first substrate and includes a gate and a second electrode, the gate is disposed on the first electrode, and the second electrode is disposed on the common electrode. The opposite substrate is disposed opposite to the array substrate and includes a second substrate and a light-shielding layer. The light-shielding layer is disposed on a side of the second substrate close to the array substrate and includes a light-shielding part. An orthographic projection of the light-shielding part on the first substrate covers an orthographic projection of the first electrode on the first substrate, an orthographic projection of the second electrode on the first substrate, and an orthographic projection of the groove on the first substrate. The display panel provided by the disclosure can reduce the number of electrodes in the common electrode layer with different polarity by designing the common electrode layer on the first substrate, thereby reducing the number of grooves for separating different electrodes, reducing the coverage area of the light-shielding layer, and improving the opening rate of the display panel.

### DESCRIPTION OF DRAWINGS

FIG. 1 is a schematic diagram of a display panel according to an embodiment of the disclosure.

FIG. 2 is a top view of an array substrate in a display panel according to a first embodiment of the disclosure.

FIG. 3 is a cross-sectional view of the display panel according to an embodiment of the disclosure taken along a direction AA′ in FIG. 2.

FIG. 4 is a cross-sectional view of the display panel according to an embodiment of the disclosure taken along a direction BB′ in FIG. 2.

FIG. 5 is a cross-sectional view of the display panel according to an embodiment of the disclosure taken along a direction CC′ in FIG. 2.

FIG. 6 is a top view of an array substrate according to a second embodiment of the disclosure.

FIG. 7 is a top view of an array substrate according to a third embodiment of the disclosure.

FIG. 8 is a top view of an array substrate according to a fourth embodiment of the disclosure.

FIG. 9 is a flow chart of a preparation method of an array substrate in a display panel according to an embodiment of the disclosure.

### DETAILED DESCRIPTION OF EMBODIMENTS

The following will describe the technical solutions in the embodiments of the disclosure in conjunction with the accompanying drawings. The described embodiments are only used to explain and illustrate the ideas of the disclosure, and should not be considered as limitations on the scope of protection of the disclosure.

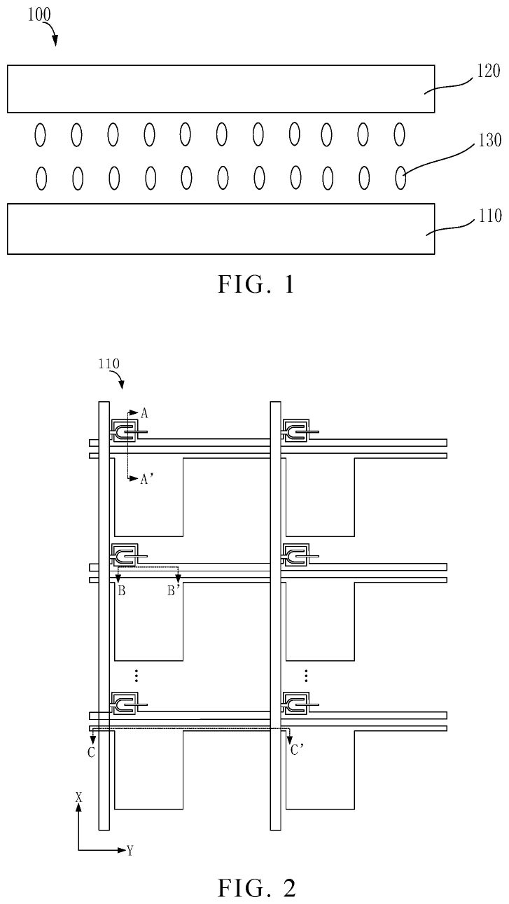

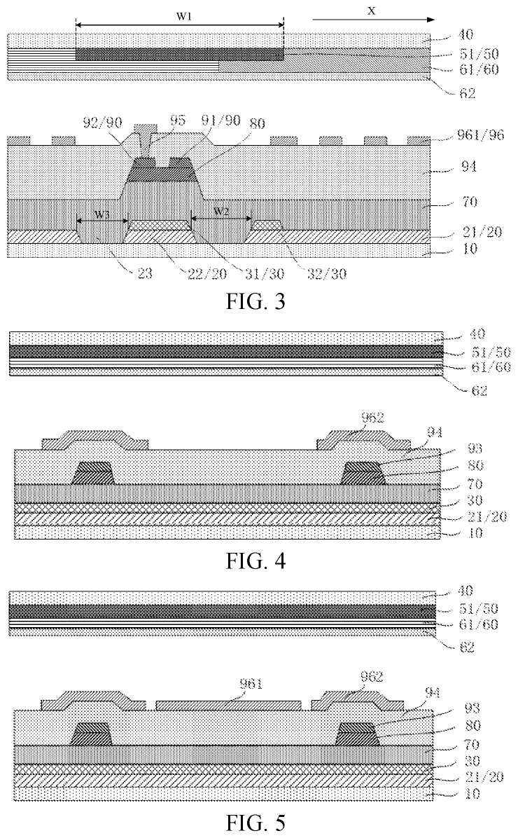

Embodiments of the disclosure provide a display panel and a preparation method thereof, which can reduce the area required for shading in the pixel unit and improve the opening rate of the display panel. As shown in FIGS. 1 to 3, a display panel 100 according to the embodiments of the disclosure includes an array substrate 110 and an opposite substrate 120. The array substrate 110 includes a first substrate 10, a common electrode layer 20, and a first metal layer 30. The common electrode layer 20 is disposed on the first substrate 10. The common electrode layer 20 includes a common electrode 21, a first electrode 22, and a groove 23. The groove 23 is disposed between the common electrode 21 and the first electrode 22. The first metal layer 30 is disposed on a side of the common electrode layer 20 away from the first substrate 10. The first metal layer 30 includes a gate 31 and a second electrode 32. The gate 31 is disposed on the first electrode 22. The second electrode 32 is disposed on the common electrode 21. The opposite substrate 120 is opposite to the array substrate 110. The opposite substrate 120 includes a second substrate 40 and a light-shielding layer 50. The light-shielding layer 50 is disposed on a side of the second substrate 40 close to the array substrate 110. The light-shielding layer 50 includes a light-shielding part 51. An orthographic projection of the light-shielding part 51 on the first substrate 10 covers an orthographic projection of the first electrode 22 on the first substrate 10, an orthographic projection of the second electrode 32 on the first substrate 10, and an orthographic projection of the groove 23 on the first substrate 10.

The display panel provided by the disclosure can reduce the number of electrodes in the common electrode layer 20 with different polarity by designing the common electrode layer 20 on the first substrate 10, thereby reducing the number of grooves 23 for separating different electrodes, reducing the coverage area of the light-shielding layer 50, and improving the opening rate of the display panel.

In the embodiments of the disclosure, a liquid crystal layer 130 is further provided between the array substrate 110 and the opposite substrate 120. Both of a material of the first substrate 10 and a material of the second substrate 40 include a material with a transparent characteristic such as glass or plastic.

In the embodiments of the disclosure, the polarity of the first electrode 22 and the polarity of the gate 31 are the same, and the polarity of the common electrode 21 and the polarity of the second electrode 32 are the same. Specifically, the first electrode 22 can be a scan line, and the second electrode 32 can be a common electrode 21 line. The scan line is parallel to the common electrode 21 line. Furthermore, a material of the first electrode 22 and a material of the second electrode 32 may be different. Both of the material of the first electrode 22 and a material of the common electrode 21 include indium tin oxide. Both of the material of the second electrode 32 and a material of the gate 31 include metal such as molybdenum, chromium, aluminum, titanium, copper, or the like. In some embodiments, both of the second electrode 32 and the gate 31 may be a laminated structure composed of a molybdenum layer and a copper layer, or a laminated structure composed of a titanium layer, a molybdenum layer, and a copper layer. Preferably, when the gate 31 is the laminated structure composed of the molybdenum layer and the copper layer, a thickness of the molybdenum layer may range from 150 angstroms to 250 angstroms, and a thickness of the copper layer may range from 3500 angstroms to 5500 angstroms.

In the embodiments of the disclosure, the common electrode layer 20 includes multiple common electrodes 21 disposed at intervals. The first electrode 22 is disposed between two adjacent common electrodes 21 arranged along a first direction X. Two opposite sides of the first electrode 22 are respectively provided with the groove 23. The orthographic projection of the light-shielding part 51 on the first substrate 10 covers an orthographic projection of two grooves 23 on the first substrate 10. Specifically, widths of cross-sectional surfaces of the two grooves 23 disposed at two opposite sides of the first electrode 22 along the first direction X are not equal.

In the embodiments of the disclosure, a width of a cross-sectional surface of the light-shielding part 51 along the first direction X ranges from 40 microns to 45 microns. Preferably, the width of the cross-sectional surface of the light-shielding part 51 along the first direction X is 42 microns. In the display panels of the related art, due to the presence of the groove 23 between the second electrode 32 and a bottom electrode (such as a pixel electrode 961), the width of the cross-sectional surface of the light-shielding part 51 along the first direction X is larger. In contrast, there is no need to dispose the groove 23 between the second electrode 32 and the common electrode 21 in the disclosure, making the width of the cross-sectional surface of the light-shielding part 51 along the first direction X smaller, and improving the opening rate.

In the embodiments of the disclosure, the opposite substrate 120 further includes a filter layer 60 disposed on a side of the light-shielding layer 50 away from the second substrate 40. The filter layer 60 includes multiple filter sheets 61, and the light-shielding part 51 is disposed between two adjacent filter sheets 61. Furthermore, the opposite substrate 120 includes a protective layer 62 disposed on a side of the filter layer 60 away from the second substrate 40. Specifically, one sub-pixel corresponds to one filter sheet 61. The filter sheets 61 includes a red filter sheet 61, a green filter sheet 61, and a blue filter sheet 61. The red filter sheet 61, the green filter sheet 61, and the blue filter sheet 61 correspond to a red sub-pixel, a green sub-pixel, and a blue sub-pixel, respectively.

As shown in FIG. 2 and FIG. 4, the array substrate 110 further includes a gate insulation layer 70, a semiconductor layer 80, and a second metal layer 90. The gate insulation layer 70 covers the common electrode layer 20 and the first metal layer 30. The semiconductor layer 80 is disposed on a side of the gate insulation layer 70 away from the first substrate 10. An orthographic projection of the semiconductor layer 80 on the first substrate 10 covers an orthographic projection of the gate 31 on the first substrate 10. The second metal layer 90 is disposed on a side of the semiconductor layer 80 away from the first substrate 10. The second metal layer 90 includes a source 91, a drain 92, and a data line 93. The source 91 and the drain 92 are disposed at intervals. The data line 93 is disposed at a side of the source 91 away from the drain 92, connected to the source 91, and extends along the first direction X. A material of the gate insulation layer 70 may be silicon nitride. A thickness of the gate insulation layer 70 is preferably ranging from 2500 angstroms to 4500 angstroms. In the disclosure, the semiconductor layer 80 and the second metal layer 90 are formed by using the same mask process, and the semiconductor layer 80 is retained below the data line 93.

In the embodiments of the disclosure, the array substrate 110 further includes a passivation layer 94. The passivation layer 94 covers the semiconductor layer 80 and the second metal layer 90. The passivation layer 94 is provided with a via hole 95 disposed corresponding to the drain 92. Preferably, a cross-sectional surface of the via hole 95 is in an inverted trapezoid shape or a cone shape along the first direction X.

As shown in FIG. 2 and FIG. 5, the array substrate 110 further includes a pixel electrode layer 96. The pixel electrode layer 96 is disposed on a side of the passivation layer 94 away from the first substrate 10. The pixel electrode layer 96 includes multiple pixel electrodes 961, and each of the pixel electrodes 961 is connected to the drain 92 through the via hole 95. A material of the pixel electrodes 961 may be indium tin oxide.

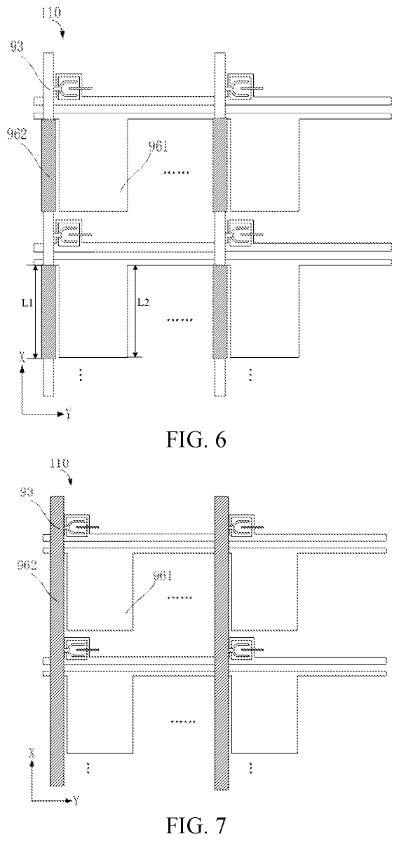

In the embodiments of the disclosure, the pixel electrode layer 96 further includes a third electrode 962. As shown in FIG. 6, the third electrode 962 is disposed above the data line 93 and between two adjacent pixel electrodes 961 arranged along the second direction Y. The first direction X is perpendicular to the second direction Y. Specifically, the first direction X is a direction in which the data line 93 extends, and the second direction Y is a direction in which the scan line extends. Specifically, a width of a cross-section surface of the third electrode 962 along the first direction X is equal to a width of a cross-section surface of the pixel electrode 961 along the first direction X.

In the embodiments of the disclosure, the polarity of the third electrode 962 is the same as the polarity of the pixel electrode 961. Specifically, the third electrode 962 is configured to receive the same voltage signal as the pixel electrode 961. A material of the third electrode 962 is the same material as the material of the pixel electrode 961, both of which include indium tin oxide or metal. The above-mentioned design can reduce the area of the light-shielding layer 50 disposed on the opposite substrate 120 and corresponding to the data line 93, which is beneficial for increasing the opening rate of the display panel, while avoiding the impact of voltage changes of the data line 93 on liquid crystals, and improving a light leakage phenomenon occurred near the data line 93.

In the embodiments of the disclosure, the width of the cross-section surface of the groove 23 along the first direction X ranges from 7 microns to 8 microns. Specifically, the width of the cross-sectional surface of the groove 23 disposed at a side of the first electrode 22 close to the second electrode 32 along the first direction X is greater than the width of the cross-sectional surface of the groove 23 disposed at a side of the first electrode 22 away from the second electrode 32 along the first direction X. Preferably, the width of the cross-sectional surface of the groove 23 disposed at the side of the first electrode 22 close to the second electrode 32 along the first direction X ranges from 7 microns to 7.4 microns, such as 7 microns, 7.1 microns, 7.2 microns, 7.3 microns, or 7.4 microns. The width of the cross-sectional surface of the groove 23 disposed at the side of the first electrode 22 away from the second electrode 32 along the first direction X ranges from 7.5 microns to 8 microns, such as 7.5 microns, 7.6 microns, 7.7 microns, 7.8 microns, 7.9 microns, or 8 microns.

As shown in FIG. 5 and FIG. 7, an orthographic projection of the third electrode 962 on the first substrate 10 covers an orthographic projection of the data line 93 on the first substrate 10. A width of the cross-sectional surface of the third electrode 962 along the second direction Y is greater than a width of the cross-sectional surface of the data line 93 along the second direction Y, and a length of the third electrode 962 is the same as a length of the data line 93. Furthermore, a thickness of the third electrode 962 and a thickness of the data line 93 in the overlapping region and the non-overlapping region of the two can be the same or different, which can avoid disposing the light-shielding layer 50 corresponding to the data line 93 in the opposite substrate 120, increasing the opening rate of the display panel. At the same time, the above-mentioned design can improve the impact of voltage changes of the data line 93 on the pixel electrodes 961, avoid undesirable phenomenon such as vertical crosstalk or uneven brightness caused by parasitic capacitance generated between the data line 93 and the pixel electrodes 961, which causes voltage offset of the pixel electrodes 961 in the region where the parasitic capacitance generates, and avoid the influence of the electric field near the data line 93 on the liquid crystals, effectively improving the light leakage phenomenon near the data line 93.

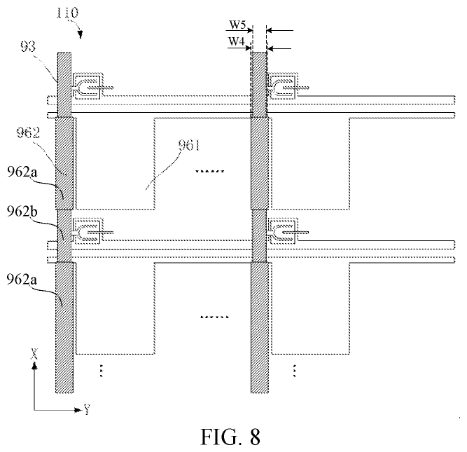

As shown in FIG. 5 and FIG. 8, the orthographic projection of the third electrode 962 on the first substrate 10 covers the orthographic projection of the data line 93 on the first substrate 10, and the third electrode 962 includes at least two first electrode parts 962a and a second electrode part 962b. Each of the first electrode parts 962a is disposed between two adjacent pixel electrodes 961 arranged along the second direction Y, and the second electrode part 962b is disposed between two adjacent first electrode parts 962a. A width of a cross-sectional surface of the first electrode part 962a along the second direction Y and a width of a cross-sectional surface of the second electrode part 962b along the second direction Y are not equal. For example, as shown in FIG. 8, the width of the cross-sectional surface of the first electrode part 962a along the second direction Y is greater than the width of the cross-sectional surface of the second electrode part 962b along the second direction Y. Furthermore, a thickness of the first electrode part 962a is greater than or equal to a thickness of the second electrode part 962b (not shown in the figures). The above-mentioned design is beneficial for improving the opening rate, while avoiding the impact of voltage changes of the data line 93 on the liquid crystals.

Embodiments of the disclosure further provides a preparation method of a display panel, which includes the following steps:
preparing an array substrate;
disposing liquid crystals on the array substrate, and
integrating the array substrate with an opposite substrate.

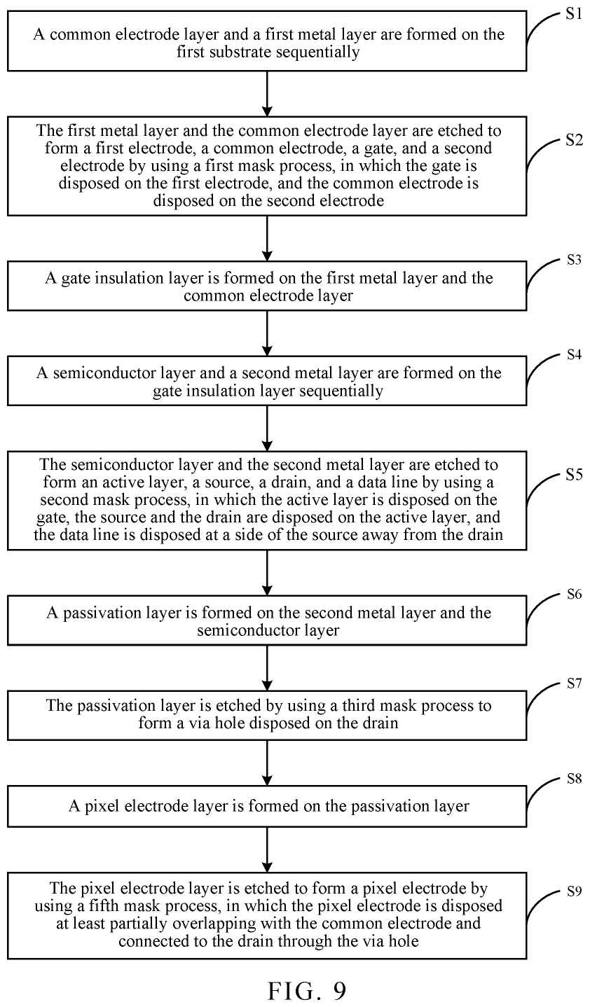

As shown in FIG. 9, steps for preparing the array substrate include the following steps.

Step S1, a common electrode layer and a first metal layer are formed on the first substrate sequentially.

Step S2, the first metal layer and the common electrode layer are etched to form a first electrode, a common electrode, a gate, and a second electrode by using a first mask process. The gate is disposed on the first electrode, and the common electrode is disposed on the second electrode.

In the embodiments of the disclosure, four photolithography processes are used to form the array substrate, and the common electrode layer and the first metal layer are etched by using the same photolithography process, which makes the common electrode layer only need to be etched to form the first electrode and the common electrode, so that the grooves only need to be formed at two opposite sides of the first electrode, thereby reducing the number of the grooves, which is beneficial for reducing the coverage area of the light-shielding layer, improving the opening rate of the display panel.

Step S3, a gate insulation layer is formed on the first metal layer and the common electrode layer.

Step S4, a semiconductor layer and a second metal layer are formed on the gate insulation layer sequentially.

Step S5, the semiconductor layer and the second metal layer are etched to form an active layer, a source, a drain, and a data line by using a second mask process. The active layer is disposed on the gate, the source and the drain are disposed on the active layer, and the data line is disposed at a side of the source away from the drain.

Step S6, a passivation layer is formed on the second metal layer and the semiconductor layer.

Step S7, the passivation layer is etched by using a third mask process to form a via hole disposed on the drain.

Step S8, a pixel electrode layer is formed on the passivation layer.

Step S9, the pixel electrode layer is etched to form a pixel electrode by using a fifth mask process. The pixel electrode is disposed at least partially overlapping with the common electrode and connected to the drain through the via hole.

A preparation method of the opposite substrate includes the following steps:
forming a light-shielding layer on a second substrate, and etching the light-shielding layer to form a light-shielding part. An orthographic projection of the light-shielding part on the first substrate covers an orthographic projection of the first electrode on the first substrate, an orthographic projection of the second electrode on the first substrate, and an orthographic projection of the groove on the first substrate.

In the embodiments of the disclosure, the pixel electrode layer further includes a third electrode, and an orthographic projection of the third electrode on the first substrate at least partially covers an orthographic projection of the data line on the first substrate.

The disclosure provides the display panel and the preparation method thereof. The display panel includes the array substrate and the opposite substrate. The array substrate includes the first substrate, the common electrode layer, and the first metal layer. The common electrode layer is disposed on the first substrate and includes the common electrode, the first electrode, and the groove, and the groove is disposed between the common electrode and the first electrode. The first metal layer is disposed on a side of the common electrode layer away from the first substrate and includes the gate and the second electrode, the gate is disposed on the first electrode, and the second electrode is disposed on the common electrode. The opposite substrate is disposed opposite to the array substrate and includes the second substrate and the light-shielding layer. The light-shielding layer is disposed on the side of the second substrate close to the array substrate and includes the light-shielding part. The orthographic projection of the light-shielding part on the first substrate covers the orthographic projection of the first electrode on the first substrate, the orthographic projection of the second electrode on the first substrate, and the orthographic projection of the groove on the first substrate. The display panel provided by the disclosure can reduce the number of electrodes in the common electrode layer with different polarity by designing the common electrode layer on the first substrate, thereby reducing the number of grooves for separating different electrodes, reducing the coverage area of the light-shielding layer, and improving the opening rate of the display panel.

The above-mentioned display panel can be applied to any product with display function such as an electronic paper, a mobile phone, a tablet, a television, a monitor, a laptop, a digital photo frame, a navigator, or the like.

The display device and the preparation method thereof according to the embodiments of the disclosure are described in detail. The description of the above-mentioned embodiments is only used to help understand a core idea of the disclosure, contents of the specification should not be interpreted as a limitation on the protection scope of the disclosure.

1. A display panel, comprising:
an array substrate, wherein the array substrate comprises:
a first substrate;
a common electrode layer disposed on the first substrate and comprising a common electrode, a first electrode, and a groove, wherein the groove is disposed between the common electrode and the first electrode; and
a first metal layer disposed on a side of the common electrode layer away from the first substrate and comprising a gate and a second electrode, wherein the gate is disposed on the first electrode, and the second electrode is disposed on the common electrode; and
an opposite substrate disposed opposite to the array substrate, wherein the opposite substrate comprises:
a second substrate; and
a light-shielding layer disposed on a side of the second substrate close to the array substrate and comprising a light-shielding part, wherein an orthographic projection of the light-shielding part on the first substrate covers an orthographic projection of the first electrode on the first substrate, an orthographic projection of the second electrode on the first substrate, and an orthographic projection of the groove on the first substrate.

2. The display panel of claim 1, wherein the common electrode layer comprises a plurality of common electrodes disposed at intervals, and the first electrode is disposed between adjacent two of the common electrodes arranged along a first direction; wherein two opposite sides of the first electrode are respectively provided with the groove, and the orthographic projection of the light-shielding part on the first substrate covers an orthographic projection of two grooves on the first substrate.

3. The display panel of claim 2, wherein a width of a cross-sectional surface of the light-shielding part along the first direction ranges from 40 microns to 45 microns.

4. The display panel of claim 2, wherein the array substrate further comprises a gate insulation layer, a semiconductor layer, and a second metal layer, wherein the gate insulation layer covers the common electrode layer and the first metal layer;
the semiconductor layer is disposed on a side of the gate insulation layer away from the first substrate, and an orthographic projection of the semiconductor layer on the first substrate covers an orthographic projection of the gate on the first substrate; and
the second metal layer is disposed on a side of the semiconductor layer away from the first substrate and comprises a source, a drain, and a data line; wherein the source and the drain are disposed at intervals, and the data line is disposed at a side of the source away from the drain and connected to the source; wherein the data line extends along the first direction.

5. The display panel of claim 4, wherein the array substrate further comprises a passivation layer, and the passivation layer covers the semiconductor layer and the second metal layer; wherein the passivation layer is provided with a via hole disposed corresponding to the drain.

6. The display panel of claim 5, wherein the array substrate further comprises a pixel electrode layer disposed on a side of the passivation layer away from the first substrate; wherein the pixel electrode layer comprises a pixel electrode, and the pixel electrode is connected to the drain through the via hole.

7. The display panel of claim 5, wherein the pixel electrode layer further comprises a third electrode disposed between two adjacent pixel electrodes arranged along a second direction, and the first direction is perpendicular to the second direction; wherein an orthographic projection of the third electrode on the first substrate at least partially covers an orthographic projection of the data line on the first substrate.

8. The display panel of claim 7, wherein a length of the third electrode along the first direction is equal to a length of the pixel electrode along the first direction.

9. The display panel of claim 7, wherein the third electrode comprises at least two first electrode parts and a second electrode part, wherein each of the first electrode parts is disposed between two adjacent pixel electrodes arranged along the second direction, and the second electrode part is disposed between two adjacent first electrode parts; wherein a width of each of the first electrode parts along the second direction and a width of the second electrode part along the second direction are not equal.

10. The display panel of claim 1, wherein a width of a cross-sectional surface of the groove along the first direction ranges from 7 microns to 8 microns.

11. A preparation method of a display panel, comprising:
preparing an array substrate;
disposing liquid crystals on the array substrate; and
integrating the array substrate with an opposite substrate;
wherein steps of preparing the array substrate comprise:
forming a common electrode layer and a first metal layer sequentially on a first substrate;
etching the first metal layer and the common electrode layer to form a first electrode, a common electrode, a gate, and a second electrode by using a first mask process, wherein the gate is disposed on the first electrode, and the second electrode is disposed on the common electrode;
forming a gate insulation layer on the first metal layer and the common electrode layer;
forming a semiconductor layer and a second metal layer sequentially on the gate insulation layer;
etching the semiconductor layer and the second metal layer to form an active layer, a source, a drain, and a data line by using a second mask process, wherein the active layer is disposed on the gate, the source and the drain are disposed on the active layer, and the data line is disposed at a side of the source away from the drain;
forming a passivation layer on the second metal layer and the semiconductor layer;
etching the passivation layer to form a via hole by using a third mask process, wherein the via hole is disposed on the drain;
forming a pixel electrode layer on the passivation layer; and
etching the pixel electrode layer to form a pixel electrode by using a fourth mask process, wherein the pixel electrode is disposed at least partially overlapping with the common electrode, and the pixel electrode is connected to the drain through the via hole;
wherein the preparation method further comprises:
preparing the opposite substrate;
wherein steps of preparing the opposite substrate comprise:
forming a light-shielding layer on a second substrate, and etching the light-shielding layer to form a light-shielding part; wherein an orthographic projection of the light-shielding part on the first substrate covers an orthographic projection of the first electrode on the first substrate, an orthographic projection of the second electrode on the first substrate, and an orthographic projection of the groove on the first substrate.

12. The preparation method of the display panel of claim 11, wherein the common electrode layer comprises a plurality of common electrodes disposed at intervals, and the first electrode is disposed between adjacent two of the common electrodes arranged along a first direction; wherein two opposite sides of the first electrode are respectively provided with the groove, and the orthographic projection of the light-shielding part on the first substrate covers an orthographic projection of two grooves on the first substrate.

13. The preparation method of the display panel of claim 12, wherein a width of a cross-sectional surface of the light-shielding part along the first direction ranges from 40 microns to 45 microns.

14. The preparation method of the display panel of claim 12, wherein the array substrate further comprises a gate insulation layer, a semiconductor layer, and a second metal layer, wherein the gate insulation layer covers the common electrode layer and the first metal layer;
the semiconductor layer is disposed on a side of the gate insulation layer away from the first substrate, and an orthographic projection of the semiconductor layer on the first substrate covers an orthographic projection of the gate on the first substrate; and
the second metal layer is disposed on a side of the semiconductor layer away from the first substrate and comprises a source, a drain, and a data line; wherein the source and the drain are disposed at intervals, and the data line is disposed at a side of the source away from the drain and connected to the source; wherein the data line extends along the first direction.

15. The preparation method of a display panel of claim 14, wherein the array substrate further comprises a passivation layer, and the passivation layer covers the semiconductor layer and the second metal layer; wherein the passivation layer is provided with a via hole disposed corresponding to the drain.

16. The preparation method of a display panel of claim 15, wherein the array substrate further comprises a pixel electrode layer disposed on a side of the passivation layer away from the first substrate; wherein the pixel electrode layer comprises a pixel electrode, and the pixel electrode is connected to the drain through the via hole.

17. The preparation method of the display panel of claim 15, wherein the pixel electrode layer further comprises a third electrode disposed between two adjacent pixel electrodes arranged along a second direction, and the first direction is perpendicular to the second direction; wherein an orthographic projection of the third electrode on the first substrate at least partially covers an orthographic projection of the data line on the first substrate.

18. The preparation method of a display panel of claim 17, wherein a length of the third electrode along the first direction is equal to a length of the pixel electrode along the first direction.

19. The preparation method of a display panel of claim 17, wherein the third electrode comprises at least two first electrode parts and a second electrode part, wherein each of the first electrode parts is disposed between two adjacent pixel electrodes arranged along the second direction, and the second electrode part is disposed between two adjacent first electrode parts; wherein a width of each of the first electrode parts along the second direction and a width of the second electrode part along the second direction are not equal.

20. The preparation method of the display panel of claim 11, wherein a width of a cross-sectional surface of the groove along the first direction ranges from 7 microns to 8 microns.
